(19) United States
(12) Patent Application Publication
(10) Pub. No.: US 2022/0305611 A1
(43) Pub. Date: Sep. 29, 2022

(54) SUBSTRATE POLISHING SYSTEM AND SUBSTRATE POLISHING METHOD

(71) Applicant: KCTECH CO., LTD., Gyeonggi-do (KR)

(72) Inventors: Hee Cheul JUNG, Seoul (KR); Geun Sik YUN, Gyeonggi-do (KR); Hyung Seob SHIM, Gyeonggi-do (KR); Sung Ho SHIN, Gyeonggi-do (KR)

(73) Assignee: KCTECH CO., LTD., Gyeonggi-do (KR)

(21) Appl. No.: 17/697,891

(22) Filed: Mar. 17, 2022

(30) Foreign Application Priority Data
Mar. 26, 2021 (KR) 10-2021-0039846

(51) Int. Cl. B24B 37/015; B24B 37/20; B24B 57/02; B24B 55/03

(52) U.S. Cl. CPC B24B 37/015; B24B 37/20; B24B 57/02; B24B 55/03

(57) ABSTRACT

A substrate polishing method for polishing a substrate through a polishing pad according to an embodiment may comprise: a preheating step of increasing the temperature of the polishing pad by supplying heated pure water to the polishing pad before polishing the substrate; and a temperature control step of controlling the temperature of the polishing pad by adjusting the temperature of the slurry supplied to the polishing pad in a polishing process of the substrate.

### CROSS-REFERENCE TO RELATED APPLICATION

This application claims the benefit of Korean Patent Application No. 10-2021-0039846 filed on Mar. 26, 2021, in the Korean Intellectual Property Office, the entire disclosure of which is incorporated herein by reference for all purposes.

### BACKGROUND

### 1. Field of the Invention

The following example embodiments relate to a substrate polishing system and a substrate polishing method.

### 2. Description of the Related Art

In manufacturing of a substrate, a chemical mechanical polishing (CMP) operation including polishing, buffing, and cleaning is required. In the CMP operation of the substrate, a process of polishing a surface to be polished of the substrate through a polishing pad is required. A CMP device is a component for polishing, buffing, and cleaning one or both surfaces of a substrate, and includes a carrier for supporting the substrate and a polishing pad for physically abrading the surface of the substrate. In a substrate polishing process, a slurry may be supplied to a substrate portion which is polished by the polishing pad.

The slurry is supplied between the substrate and the polishing pad so that polishing of the substrate may be performed through mechanical friction by slurry particles and polishing pad surface protrusions, and at the same time, the surface of the substrate may be polished through a chemical reaction by a composition comprising the slurry. In this case, the chemical reaction through the slurry may induce a change in the physical properties of the polishing pad, and such a chemical reaction is related to the temperature of the slurry and may ultimately affect the removal rate of the substrate.

Conventionally, the slurry was stored in a tank and the temperature of the stored slurry was collectively controlled to supply the slurry to the substrate. However, the temperature was changed in the flow process of the slurry, or it was difficult to finely control the temperature of the slurry supplied to the polishing pad.

Therefore, there is a need for a technique for uniformly and finely controlling the temperature of the slurry supplied in the substrate polishing process.

### SUMMARY

Example embodiments provide a substrate polishing system and method capable of controlling the temperature of the polishing pad through a slurry supplied to a polishing pad in a substrate polishing process.

Example embodiments provide a substrate polishing system and method capable of simultaneously securing an increase in the removal rate of a substrate and an effect of preventing deterioration through temperature control of a polishing pad.

According to an aspect, there may be provided a substrate polishing method for polishing a substrate through a polishing pad, the substrate polishing method comprising: a preheating step of increasing the temperature of the polishing pad by supplying heated pure water to the polishing pad before polishing the substrate; and a temperature control step of controlling the temperature of the polishing pad by adjusting the temperature of the slurry supplied to the polishing pad in a polishing process of the substrate.

Pure water supplied in the preheating step may have a temperature of 20 to 80° C.

The slurry supplied in the temperature control step may have a temperature of 0 to 80° C.

The temperature of the polishing pad may be decreased in the last period of the polishing process.

The cooling step may include a cooled slurry supply step of supplying a cooled slurry having a temperature of −10 to 10° C. to the polishing pad.

The cooling step may include a high-flow rate pure water supply step of supplying pure water to the polishing pad at a flow rate of 9 to 13 lpm.

The high-flow rate pure water supply step may be performed for 1 to 2 seconds.

The cooling step may include a pressing force reduction step of reducing a pressure for pressing the substrate against the polishing pad.

The pressing force reduction step may be a step of reducing the pressure to a pressure corresponding to ⅔ of the pressure for pressing the substrate against the polishing pad in the polishing process.

According to another aspect, there may be provided a substrate polishing system including: a supply arm which is disposed on an upper portion of a polishing pad for polishing a substrate and forms an internal accommodation space; a first heating module which is disposed inside the accommodation space and supplies heated pure water to the polishing pad in order to increase the temperature of the polishing pad before polishing the substrate; a second heating module which is disposed inside the accommodation space and supplies a heated slurry to the polishing pad in order to control the temperature of the polishing pad in the polishing process of the substrate; and a cooling module which is disposed inside the accommodation space and supplies a cooled slurry to the polishing pad in order to control the temperature of the polishing pad in the polishing process of the substrate.

Pure water supplied from the first heating module before polishing the substrate may have a temperature of 20 to 80° C.

The slurry supplied from the second heating module in the polishing process may have a temperature of 0 to 80° C.

The cooling module may supply the cooled slurry to the polishing pad in order to reduce the temperature of the polishing pad in the last period of the polishing process.

The slurry supplied from the cooling module may have a temperature of −10 to 10° C. in the last period of the polishing process.

The substrate polishing system may further include a pure water supply module for supplying pure water to the polishing pad at a flow rate of 9 to 13 lpm in the last period of the polishing process.

The pure water supply module may be configured to supply pure water for 1 to 2 seconds.

The pressure for pressing the substrate against the polishing pad may be reduced in the last period of the polishing process.

The pressure for pressing the substrate in the last period of the polishing process may be ⅔ of the pressure for pressing the substrate in the polishing process.

According to another aspect, there may be provided a substrate polishing method for polishing a substrate through a polishing pad, the substrate polishing method comprising the steps of: controlling the temperature of the polishing pad to a first temperature in the early period of the polishing process of the substrate; controlling the temperature of the polishing pad to a second temperature in the middle period of the polishing process of the substrate; and controlling the temperature of the polishing pad to a third temperature in the last period of the polishing process of the substrate.

The step of controlling the temperature of the polishing pad to the first temperature may include a step of supplying heated pure water to the polishing pad to increase the temperature of the polishing pad to the first temperature.

The step of controlling the temperature of the polishing pad to the second temperature may include a step of controlling the temperature of the polishing pad to the second temperature by adjusting the temperature of the slurry supplied to the polishing pad.

The step of controlling the temperature of the polishing pad to the third temperature may include a step of supplying the cooled slurry to the polishing pad.

The step of controlling the temperature of the polishing pad to the third temperature may include a step of supplying pure water to the polishing pad at a flow rate of 9 to 13 lpm.

The step of controlling the temperature of the polishing pad to the third temperature may include a step of reducing the pressure for pressing the substrate against the polishing pad.

Additional aspects of example embodiments will be set forth in part in the description which follows and, in part, will be apparent from the description, or may be learned by practice of the disclosure.

According to an example embodiment, the substrate polishing system and method can adjust the temperature of the polishing pad through the slurry supplied to the polishing pad in the substrate polishing process.

According to an example embodiment, the substrate polishing system and method can simultaneously secure an increase in the removal rate of the substrate and an effect of preventing deterioration through control of the temperature of the polishing pad.

According to an example embodiment, effects of the substrate polishing system and method are not limited to those mentioned above, and other effects not mentioned will be clearly understood by those with ordinary skill in the art from the following description.

### BRIEF DESCRIPTION OF THE DRAWING

These and/or other aspects, features, and advantages of the invention will become apparent and more readily appreciated from the following description of example embodiments, taken in conjunction with the accompanying drawings of which:

FIG. 1 is a graph showing a correlation between the temperature of a slurry supplied and the removal rate of a substrate in a substrate polishing process;

FIG. 2 is a graph illustrating a correlation between the temperature of the slurry supplied and the flatness of the substrate surface in the substrate polishing process;

FIG. 3 is a perspective view of a substrate polishing system according to an example embodiment;

FIG. 4 is a plan view of the substrate polishing system according to an example embodiment;

FIG. 5 is a perspective view of a slurry supply device according to an example embodiment;

FIG. 6 is a perspective view of a heating module according to an example embodiment;

FIG. 7 is a plan view of the heating module according to an example embodiment;

FIG. 8 is a perspective view of a cooling module according to an example embodiment;

FIG. 9 is a flowchart of a substrate polishing method according to an example embodiment; and

FIG. 10 is a flowchart of a cooling step according to an example embodiment.

### DETAILED DESCRIPTION

Hereinafter, embodiments will be described in detail with reference to exemplary drawings. In adding reference numerals to the components of each drawing, it should be noted that the same components are given the same reference numerals as much as possible even though they are indicated on different drawings. Further, in describing the embodiment, if it is determined that a detailed description of a related known configuration or function interferes with the understanding of the embodiment, the detailed description thereof will be omitted.

Further, in describing a constituent element of the embodiment, a term such as first, second, A, B, (a), (b), or the like may be used. This term is only for distinguishing the constituent element from other constituent elements, and essence, order, sequence, or the like of the corresponding constituent element is not limited by the term. When it is described that a constituent element is “linked”, “coupled”, or “connected” to other constituent element, the constituent element may be directly linked or connected to the other constituent element, but it should be understood that another constituent element may also be “linked”, “coupled”, or “connected” between the respective constituent elements.

A constituent element included in any one embodiment and a constituent element including a common function will be described using the same name in other embodiment. Unless otherwise stated, a description described in any one embodiment may also be applied to other embodiment, and a detailed description will be omitted in the overlapping range.

Hereinafter, a substrate polishing system including a slurry supply device will be described. The substrate polishing system may perform chemical mechanical planarization (CMP) of the substrate. The CMP process may include physical polishing process in which a substrate is physically abraded through a polishing pad and a chemical polishing process using the chemical reaction of a slurry.

The substrate on which the substrate polishing system is used may be a silicon wafer for manufacturing a semiconductor device. The substrate may be formed in a multilayer structure formed by stacking metal or insulator layers, and planarization of the surface should be performed through a polishing process in order to secure a target profile.

A slurry may be supplied in the polishing process of the substrate. The slurry is supplied between the substrate and the polishing pad to physically polish the surface of the substrate, and at the same time it chemically reacts with the material on the substrate surface to form a compound. Meanwhile, the slurry may have a close influence on the polishing state of the substrate surface in the substrate polishing process.

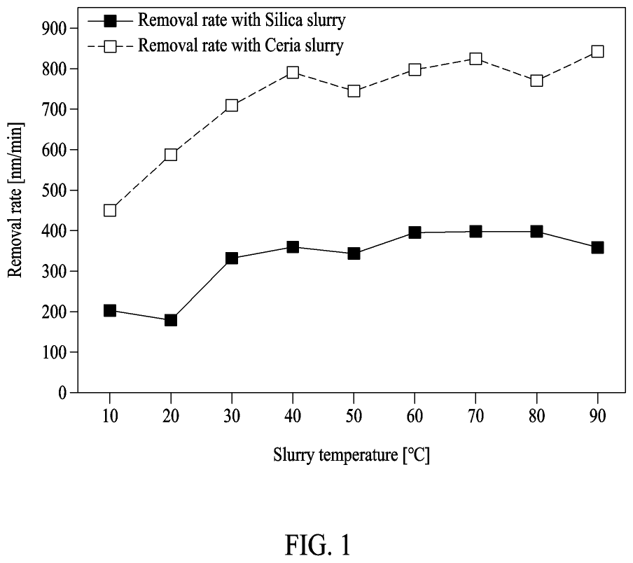

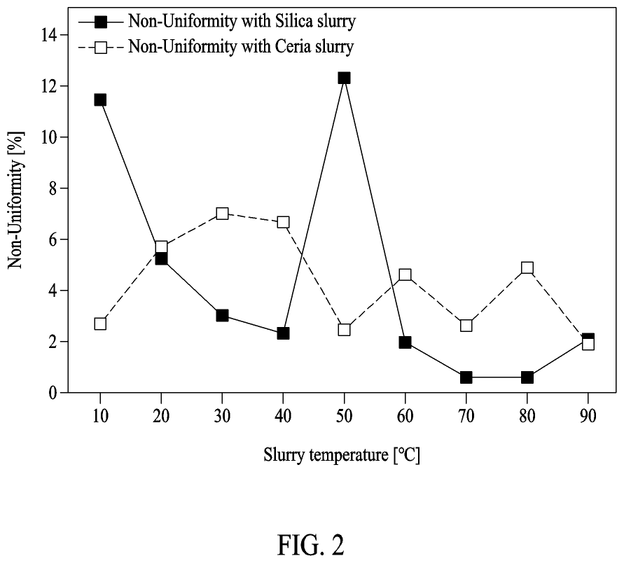

FIG. 1 is a graph showing a correlation between the temperature of a slurry supplied and the removal rate of a substrate in a substrate polishing process, and FIG. 2 is a graph illustrating a correlation between the temperature of the slurry supplied and the flatness of the substrate surface in the substrate polishing process.

Referring to FIG. 1, it can be confirmed that the temperature of the slurry is related to the removal rate (RR) of the substrate. Although the value of the removal rate varies depending on the type of slurry, it can be confirmed that the removal rate of the substrate increases as the temperature of the slurry increases up to a certain temperature. Further, when a certain temperature is exceeded, it can be confirmed that the removal rate of the substrate is maintained within a certain range. Therefore, it can be understood that the removal rate of the substrate is improved when a slurry of a certain temperature or higher is supplied in the polishing process of the substrate. The increase in the removal rate of the substrate shortens the substrate abrasion time to a target thickness so that the time required for polishing the substrate may be ultimately reduced.

Referring to FIG. 2, it can be confirmed that the temperature of the slurry supplied in the substrate polishing process is related to the flatness of the substrate surface. Although there is a difference in the non-uniformity value for the temperature range depending on the type of slurry, it can be confirmed that the non-uniformity of the substrate surface is low in a specific slurry temperature range. In general, a dishing phenomenon in which a specific portion is hollowly dented may occur due to a difference in materials constituting the layer in the process of polishing a multilayered layer. Accordingly, when the temperature of the slurry supplied in the polishing process of the substrate is adjusted, the occurrence of dishing on the surface of the substrate may be minimized to greatly reduce the surface non-uniformity of the substrate, thereby improving the quality of the substrate.

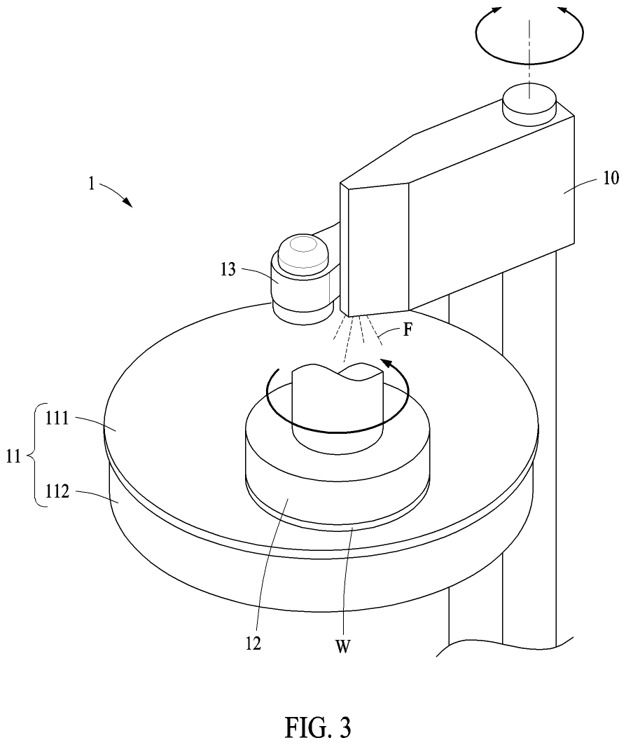

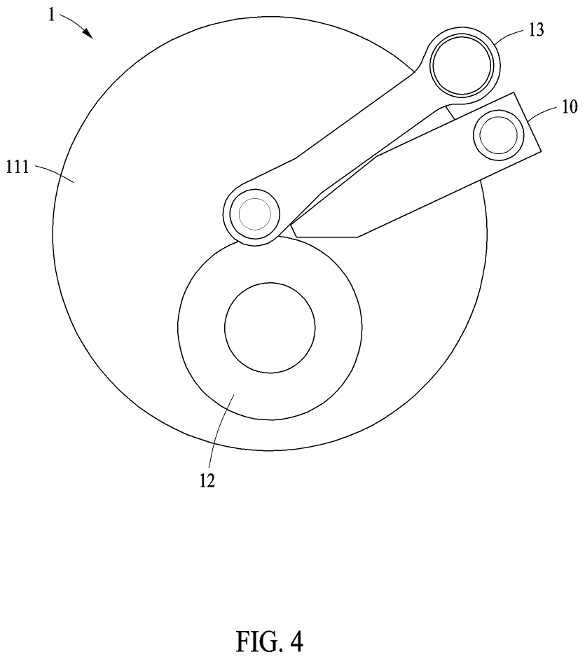

FIG. 3 is a perspective view of a substrate polishing system according to an example embodiment, and FIG. 4 is a plan view of the substrate polishing system according to an example embodiment.

Referring to FIGS. 3 and 4, a substrate polishing system 1 according to an embodiment may polish a substrate W. The substrate polishing system 1 may improve the removal rate and polishing uniformity of the substrate W by adjusting the temperature of the polishing process of the substrate W through the slurry supplied in the polishing process of the substrate W. The substrate polishing system 1 may include a carrier head 12, a polishing surface plate 11, a conditioner 13, and a slurry supply device 10.

The carrier head 12 may grip the substrate W. The carrier head 12 may polish the substrate W by pressing it against a polishing pad 111 to be described later in a state that the substrate W is gripped. The carrier head 12 may rotate in a state that it grips the substrate W. As shown in FIG. 3, the carrier head 12 may rotate about an axis perpendicular to the surface of the substrate W. The carrier head 12 may move in a first direction and a second direction perpendicular to the first direction on a plane parallel to the surface of the substrate W. Accordingly, the position of the substrate W above the polishing pad 111 may be adjusted according to the movement of the carrier head 12.

The polishing surface plate 11 may be in contact with the substrate W gripped by the carrier head 12 to polish the substrate W. The polishing surface plate 11 may include a rotary table 112 and a polishing pad 111.

The rotary table 112 may rotate about an axis perpendicular to the ground. The polishing pad 111 may be provided on the upper portion of the rotary table 112. The polishing pad 111 may have a groove formed on the surface thereof. The polishing pad 111 may have a larger area than the substrate W. The substrate W may come into contact with a local point of the polishing pad 111 in the process of polishing the substrate W. Hereinafter, for convenience of description, a portion of the polishing pad 111 in contact with the substrate W will be referred to as a polishing portion.

The conditioner 13 may condition the surface of the polishing pad 111. As the polishing is performed, the surface of the polishing pad 111 may be worn, and for example, the groove formed on the surface of the polishing pad 111 may become flat. Since the wear of the groove reduces the polishing efficiency of the substrate W, the conditioner 13 may restore the surface of the polishing pad 111 to have sufficient roughness through the regeneration operation of scraping the surface of the polishing pad 111. The conditioner 13 may include a conditioning pad contacting the polishing pad 111, and a conditioning head rotating the conditioning pad with respect to the polishing pad 111.

The slurry supply device 10 may spray the slurry to the polishing pad 111. The slurry supply device 10 may adjust the temperature of the polishing pad 111 through control of the temperature of the slurry sprayed to the polishing pad 111 in the polishing process of the substrate W. In other words, the slurry supply device 10 may adjust the temperature of the polishing process of the substrate W through the slurry.

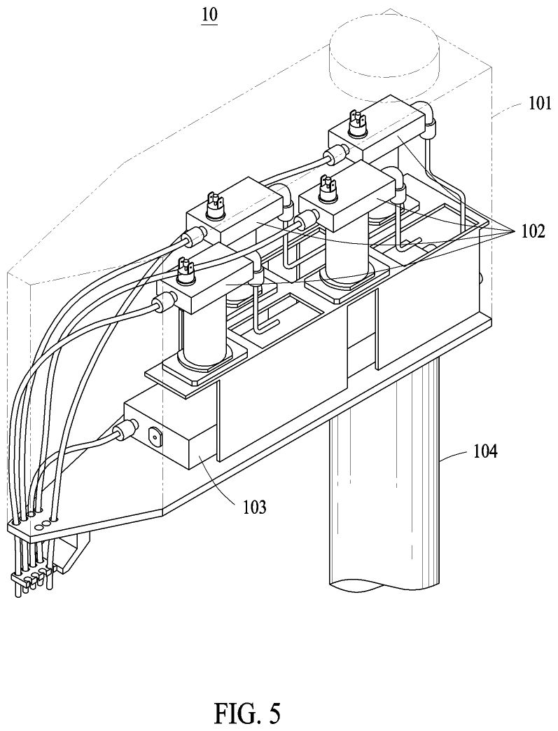

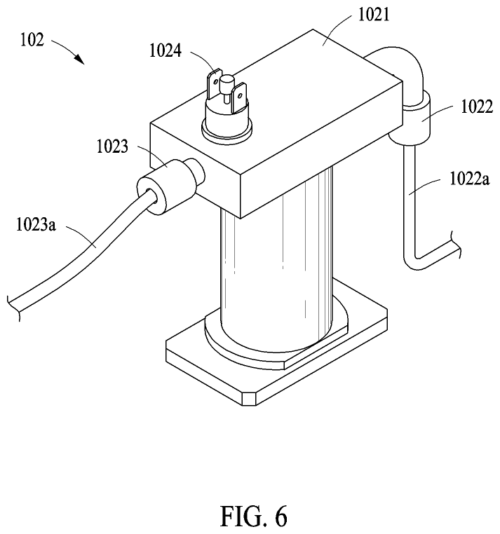

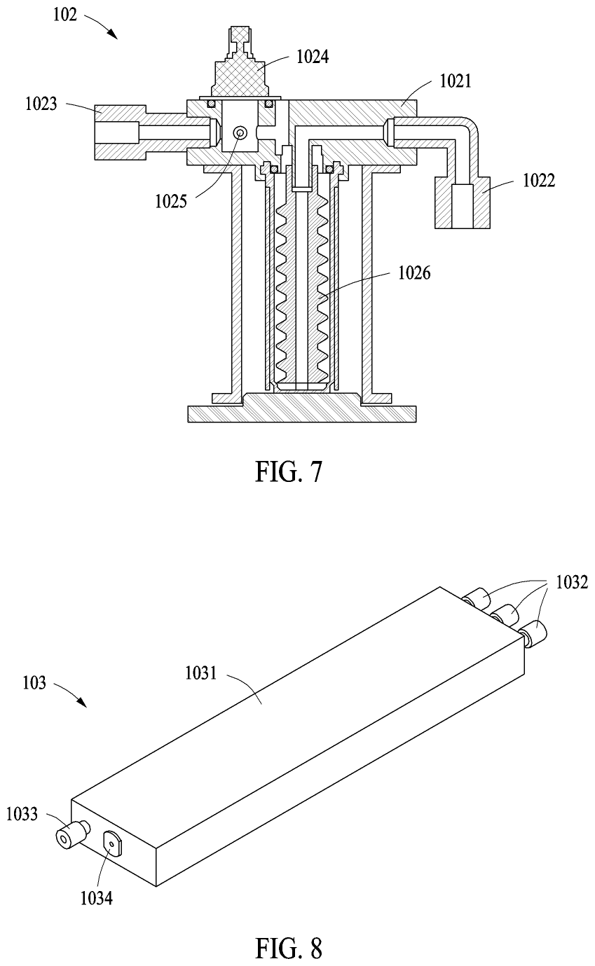

FIG. 5 is a perspective view of a slurry supply device 10 according to an example embodiment, FIG. 6 is a perspective view of a heating module 102 according to an example embodiment, FIG. 7 is a plan view of the heating module 102 according to an example embodiment, and FIG. 8 is a perspective view of a cooling module 103 according to an example embodiment.

Referring to FIGS. 5 to 8, the slurry supply device 10 according to an embodiment may include a rotating part 104, a supply arm 101, a heating module 102, and a cooling module 103.

The rotating part 104 may be disposed outside the polishing pad 111. The rotating part 104 may have a longitudinal direction perpendicular to the surface of the polishing pad 111. The supply arm 101 may be disposed on an upper portion of the polishing pad 111 to supply the slurry to the polishing pad 111. The supply arm 101 may have its one side connected to the rotating part 104, and be rotatably connected to the rotating part 104 to perform a swing action on the upper portion of the polishing pad 111. The supply arm 101 may include an internal accommodation space. The heating module 102 and the cooling module 103 which are to be described later may be disposed inside the accommodation space.

The supply arm 101 may include a support plate constituting the bottom surface of the accommodation space, and a fixing plate disposed within the accommodation space and spaced apart from the support plate by a predetermined distance. In this case, the cooling module may be disposed on a lower side of the fixing plate, and a plurality of heating modules may be each disposed on an upper surface of the fixing plate.

Meanwhile, as will be described later, the plurality of heating modules and cooling module independently control the temperature of the slurry and discharge it, and a discharge pipe for the flow of the discharged slurry may be connected to each of the heating modules and cooling module. In this case, an opening-forming opening may be formed in the support plate so that the discharge pipe exits to the outside of the supply arm 101, and a discharge pipe fixing part in which an end portion of the discharge pipe protruding to the outside is inserted and fixed may be formed in the lower side of the opening. An insertion hole into which the discharge pipe is inserted may be formed in the discharge pipe fixing part.

The heating module 102 may be disposed inside the supply arm 101. The heating module 102 may heat the slurry supplied therein, and spray the heated slurry to the polishing pad 111 through the supply arm 101. A plurality of heating modules 102 may be provided inside the supply arm 101. In this case, the slurry or pure water may be heated through the plurality of heating modules 102 and supplied to the polishing pad 111. For example, at least one of the plurality of heating modules 102 may be divided into a slurry heating module for heating and discharging the slurry, and a preliminary heating module for heating pure water (deionized water) and supplying it to the polishing pad 111. The plurality of heating modules 102 are formed in the same structure, and the heating modules 102 may each individually receive and heat a fluid, and each discharge the heated fluid to the outside of the supply arm 101. The temperatures of the fluids passing through the respective heating modules 102 may be individually set.

The heating module 102 may include a housing 1021, a heater 1026, a heater sensor, a temperature sensor 1024, and a temperature controller.

The housing 1021 may have a flow path formed therein. An inlet 1022 and an outlet 1023 communicating with the flow path formed therein may be respectively formed in the outer surface of the housing 1021. The fluid supplied into the housing 1021 through the inlet 1022 may flow through the flow path in the housing 1021 and then be discharged to the outside of the housing 1021 through the outlet 1023. A supply pipe and a discharge pipe are connected to the inlet 1022 and the outlet 1023 respectively, a fluid to be heated may be supplied into the heating module 102 through the supply pipe, and the fluid passing through the heating module 102 may be discharged through the discharge pipe.

The heater 1026 may heat the fluid flowing through the flow path. The heater may include a heating element installed inside the housing 1021 to directly apply heat to the flow path. On the other hand, the heater 1026 may include a heating flow path communicating with the flow path of the housing 1021 as shown in FIG. 7, and in this case, the fluid passing through the flow path of the housing 1021 may be heated while passing through the heating flow path. For example, the flow path formed in the housing may include a first heating flow path having one side connected to the inlet and the other side connected to an inlet of the heating flow path, and a second heating flow path having one side connected to an outlet of the heating flow path and the other side connected to the outlet.

The heater sensor may detect the temperature of the heater 1026. The heater sensor may prevent the heating module 102 from being damaged due to overheating of the heater.

The temperature sensor 1024 may be installed around the outlet, and may detect the temperature of the fluid discharged through the outlet 1023. Since the fluid discharged to the outside of the housing 1021 through the outlet 1023 is directly sprayed to the polishing pad 111, the temperature of the fluid sprayed to the polishing pad 111 may be detected in real time through the temperature sensor. Meanwhile, a temperature measuring port communicating with the outside of the housing may be formed in a flow path portion adjacent to the outlet, and in this case, the temperature sensor may be a bi-metal temperature sensor installed on the outer surface of the housing in which the temperature measuring port is formed.

The temperature controller may control the operation of the heater based on the temperature of the fluid detected by the temperature sensor. Accordingly, the temperature of the fluid discharged to the polishing pad 111 through the outlet may be adjusted.

The cooling module 103 may be disposed inside the accommodation space of the supply arm 101. The cooling module 103 may receive the slurry and cool it, and spray the cooled slurry onto the polishing pad 111 through the supply arm 101.

The cooling module 103 may receive the slurry independently from the heating module 102 and discharge it to the outside of the supply arm 101. The cooling module 103 may include a cooling housing 1031, a first flow path (not shown), a second flow path (not shown), and a heat exchange part (not shown).

The cooling housing 1031 may form an exterior of the cooling module 103. A first flow path and a second flow path separated from each other may be formed in the housing 1021. The slurry and cooling water may respectively flow through the first flow path and the second flow path. In an outer portion of the housing 1021, a first inlet 1032 and a first outlet 1033 which are connected to the first flow path may be formed, and a second inlet 1034 and a second outlet 1035 which are connected to the second flow path may be respectively formed.

The slurry may be supplied into the cooling housing through the first inlet 1032, flow through the first flow path, and then be discharged to the outside of the housing 1021 through the first outlet 1033. A discharge pipe for flowing the cooled slurry to the polishing pad 111 may be connected to the first outlet 1033. Similarly, cooling water may be supplied into the cooling housing through the second inlet 1034, flow through the second flow path, and then be discharged to the outside of the housing 1021 through the second outlet 1035.

The heat exchange part may be installed inside the housing 1021. The heat exchange part may include, for example, a Peltier element. The heat exchange part may perform heat exchange between the slurry flowing through the first flow path and cooling water flowing through the second flow path. The heat exchange part may move heat in a direction from the slurry flowing through the first flow path toward cooling water flowing through the second flow path. Accordingly, the slurry passing through the first flow path may be discharged to the polishing pad 111 in a state that the temperature is reduced.

Meanwhile, a discharge pipe for discharging the slurry may be connected to the heating module 102 and the cooling module 103 respectively, and a discharge pipe fixing part for fixing end portions of the plurality of discharge pipes in the direction of the polishing pad 111 may be formed in the supply arm 101.

According to such a structure, the slurry supply device 10 may selectively adjust the temperature of the polishing pad 111 by supplying slurries of different temperatures to the polishing pad 111 through the operation of the heating module 102 and the cooling module 103. Accordingly, the slurry supply device 10 may optimally adjust the process temperature acting on the substrate W in the polishing process of the substrate W through the temperature adjustment of the polishing pad 111.

In particular, the slurry supply device 10 may improve the removal rate and polishing uniformity of the substrate W by spraying pure water heated through the heating module 102 to the polishing pad 111 before the polishing of the substrate W is performed, thereby adjusting the temperature of the polishing pad 111 to an optimal range at a time point when the polishing of the substrate W is started. In particular, since the slurry whose temperature is adjusted through the slurry supply device 10 is directly supplied to the polishing pad 111, it may be minimized that the temperature of the slurry is changed in the flow process of the slurry.

Hereinafter, a method for polishing a substrate according to an embodiment will be described. In describing the method for polishing a substrate, descriptions overlapping with the previously described descriptions will be omitted.

The method for polishing a substrate may polish the substrate by pressing the substrate against a polishing pad. The method for polishing a substrate may effectively adjust the polishing process temperature of the substrate through the temperature of the slurry supplied to the polishing pad.

The method for polishing a substrate may comprise a preheating step, a heating step, and a cooling step.

In the preheating step, heated pure water may be supplied to the polishing pad to increase the temperature of the polishing pad. The preheating step may be performed before the substrate is polished, thereby preheating the polishing pad. Accordingly, the time required for the temperature of the polishing pad to reach the optimum range in the subsequent substrate polishing process may be shortened.

In the heating step, the heated slurry may be supplied to the polishing pad to position the temperature of the polishing pad in a set temperature range. The heating step may be performed in the polishing process of the substrate. The optimal process temperature required for substrate polishing may be achieved through the slurry supplied in the heating step. The heating step may increase the removal rate between the polishing processes of the substrate, thereby shortening the substrate polishing time to reach the target profile, and ultimately improving the productivity of the substrate polishing process.

The cooling step may reduce the temperature of the polishing pad to a set temperature range by supplying the cooled slurry to the polishing pad after the heating step. In the latter stage of the substrate polishing process, dishing phenomenon may occur on the substrate surface due to a material difference in multiple layers. When the temperature of the polishing process is reduced, the occurrence of dishing phenomenon may be minimized to increase the polishing uniformity of the substrate surface, and improve the yield of the substrate consequently.

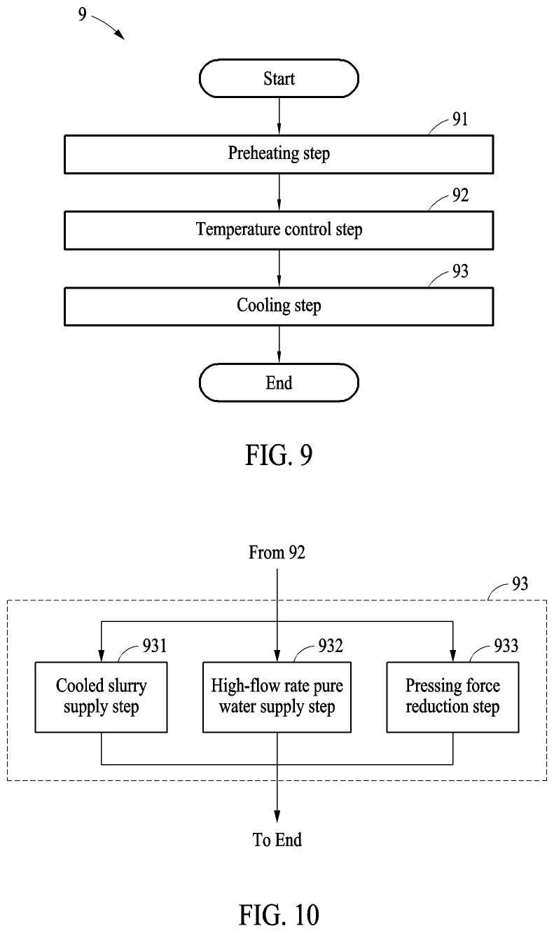

FIG. 9 is a flowchart of a substrate polishing method according to an example embodiment, and FIG. 10 is a flowchart of a cooling step according to an example embodiment.

Hereinafter, a substrate polishing method 9 according to an embodiment will be described with reference to FIGS. 9 and 10. In describing the substrate polishing method 9, descriptions overlapping with the previously described descriptions will be omitted. The substrate polishing method 9 may be performed by the above-described substrate polishing system.

The polishing process of the substrate to be described below may be a broad concept including not only a direct polishing process of rubbing the substrate against the polishing pad, but also a process of preparing for polishing and a process of finishing the polishing. For example, the polishing process may include the early period of the polishing process, the middle period of the polishing process, and the last period of the polishing process. For example, the early period of the polishing process may include a process of preparing for polishing before performing polishing by directly rubbing the substrate against the polishing pad. For example, the middle period of the polishing process may include a process of directly rubbing the substrate against the polishing pad. For example, the middle period of the polishing process may include a main polishing process. For example, the last period of the polishing process may include a process of finishing the polishing. For example, the last period of the polishing process may include an over-polishing process of further polishing the substrate after the main polishing process. For example, the last period of the polishing process may include a process of reducing the removal rate or reducing the polishing pressure.

The substrate polishing method 9 according to an embodiment may comprise a preheating step 91, a temperature control step 92, and a cooling step 93.

The preheating step 91 may be a step of increasing the temperature of the polishing pad by supplying heated pure water to the polishing pad. The preheating step 91 may be performed in the early period of the polishing process. For example, the preheating step 91 may be performed prior to polishing the substrate. In the early period of the polishing process, the temperature of the polishing pad may be adjusted to the first temperature. For example, pure water supplied in the preheating step 91 may have a temperature of 20 to 80° C. The preheating step 91 may be performed by the first heating module. In other words, the first heating module may supply heated pure water to the polishing pad in order to increase the temperature of the polishing pad before polishing the substrate. The polishing pad may be preheated through such a preheating step 91. Accordingly, the time required for the temperature of the polishing pad to reach the optimum range in the subsequent substrate polishing process may be shortened.

The temperature control step 92 may be a step of controlling the temperature of the polishing pad by adjusting the temperature of the slurry supplied to the polishing pad. The temperature control step 92 may be performed in the polishing process of the substrate. For example, the temperature control step 92 may be performed in the middle period of the polishing process. For example, the temperature control step 92 may be performed in the main polishing process of the substrate. The temperature of the polishing pad may be adjusted to the second temperature in the middle period of the polishing process. The second temperature may be different from the first temperature. For example, the slurry supplied in the temperature control step 92 may have a temperature of 0 to 80° C. In the temperature control step 92, a slurry having a temperature higher than that of a current polishing pad may be supplied in order to increase the temperature of the polishing pad, or a slurry having a temperature lower than that of the current polishing pad may be supplied in order to decrease the temperature of the polishing pad. The temperature control step 92 may be performed by the second heating module and the cooling module. In other words, the second heating module may supply the heated slurry to the polishing pad in order to control the temperature of the polishing pad in the polishing process of the substrate, and the cooling module may supply the cooled slurry to the polishing pad in order to control the temperature of the polishing pad in the polishing process of the substrate. The second heating module and the cooling module may be interworked with each other and controlled in order to achieve a target temperature. The polishing process time of the substrate may be shortened, and the occurrence of dishing phenomenon may be minimized by such a temperature control.

The cooling step 93 may be a step of reducing the temperature of the polishing pad. The cooling step 93 may be performed in the last period of the polishing process. For example, the cooling step 93 may be performed in the over-polishing process of the substrate. The temperature of the polishing pad may be adjusted to a third temperature in the last period of the polishing process. The third temperature may be different from the first temperature or the second temperature. For example, the third temperature may be lower than the second temperature.

The cooling step 93 may include at least one of a cooled slurry supply step 931, a high-flow rate pure water supply step 932, and a pressing force reduction step 933.

The cooled slurry supply step 931 may be a step of supplying a cooled slurry having a temperature of −10 to 10° C. to the polishing pad. For example, the cooled slurry may have a temperature of about 0° C. The cooled slurry supply step 931 may be performed by a cooling module. In other words, the cooling module may supply the cooled slurry to the polishing pad in order to reduce the temperature of the polishing pad in the last period of the polishing process of the substrate. The temperature of the polishing pad may be reduced by supplying the cooled slurry to the polishing pad through the cooled slurry supply step 931.

The high-flow rate pure water supply step 932 may be a step of supplying pure water to the polishing pad at a high flow rate. For example, pure water may be supplied at a flow rate of 9 to 13 lpm. For example, pure water may be supplied at a flow rate of about 11 lpm. The high-flow rate pure water supply step 932 may be performed for 1 to 2 seconds. For example, the high-flow rate pure water supply step 932 may be performed for 1 to 2 seconds in the early period of the over-polishing process. The high-flow rate pure water supply step 932 may be performed by the pure water supply module. In other words, the pure water supply module may supply pure water to the polishing pad at a flow rate of 9 to 13 lpm in the last period of the polishing process. Meanwhile, the pure water supply module may have the same configuration as the first heating module, that is not a separate configuration. As described above, when pure water of a high flow rate is supplied to the polishing pad, the temperature of the polishing pad may be rapidly reduced.

The pressing force reduction step 933 may be a step of reducing the pressure for pressing the substrate against the polishing pad. For example, the pressing force may be reduced by reducing the pressure in each chamber of the membrane provided in the carrier head. For example, the pressing force reduction step 933 may be a step of reducing the pressure to a pressure corresponding to ⅔ of the pressure for pressing the substrate against the polishing pad in the polishing process (e.g., the main polishing process). As such, when the pressure applied to the substrate is reduced, the temperature of the polishing pad may be reduced.

The cooled slurry supply step 931, the high-flow rate pure water supply step 932, and the pressing force reduction step 933 may be performed simultaneously or individually. For example, the high-flow rate pure water supply step 932 may be performed at the beginning of the last period of the polishing process, and then the cooled slurry supply step 931 and the pressing force reduction step 933 may also be performed. Polishing uniformity and flatness may be improved by reducing the temperature of the polishing pad in the last period of the polishing process through the cooling step 93.

As described above, although the embodiments have been described by the limited drawings, those with ordinary skill in the art may apply various modifications and alterations from the above-mentioned description. For example, appropriate results can be achieved although described techniques are carried out in an order different from a described method, and/or described elements such as structures, devices, etc. are combined or mixed in a form different from the described method, or replaced or substituted with other elements or equivalents.

What is claimed is:

1. A substrate polishing method for polishing a substrate through a polishing pad, the substrate polishing method comprising:
a preheating step of increasing the temperature of the polishing pad by supplying heated pure water to the polishing pad before polishing the substrate; and
a temperature control step of controlling the temperature of the polishing pad by adjusting the temperature of the slurry supplied to the polishing pad in a polishing process of the substrate.

2. The substrate polishing method of claim 1, wherein pure water supplied in the preheating step has a temperature of 20 to 80° C.

3. The substrate polishing method of claim 1, wherein the slurry supplied in the temperature control step has a temperature of 0 to 80° C.

4. The substrate polishing method of claim 1, further comprising a cooling step of decreasing the temperature of the polishing pad in the last period of the polishing process.

5. The substrate polishing method of claim 4, wherein the cooling step includes: a cooled slurry supply step of supplying a cooled slurry having a temperature of −10 to 10° C. to the polishing pad; or a high-flow rate pure water supply step of supplying pure water to the polishing pad at a flow rate of 9 to 13 lpm.

6. The substrate polishing method of claim 4, wherein the cooling step includes a pressing force reduction step of reducing a pressure for pressing the substrate against the polishing pad.

7. The substrate polishing method of claim 6, wherein the pressing force reduction step is a step of reducing the pressure to a pressure corresponding to ⅔ of the pressure for pressing the substrate against the polishing pad in the polishing process.

8. A substrate polishing system including:
a supply arm being configured to be disposed on an upper portion of a polishing pad for polishing a substrate and form an internal accommodation space;
a first heating module being configured to be disposed inside the accommodation space and supply heated pure water to the polishing pad in order to increase the temperature of the polishing pad before polishing the substrate;
a second heating module being configured to be disposed inside the accommodation space and supply a heated slurry to the polishing pad in order to control the temperature of the polishing pad in the polishing process of the substrate; and
a cooling module being configured to be disposed inside the accommodation space and supply a cooled slurry to the polishing pad in order to control the temperature of the polishing pad in the polishing process of the substrate.

9. The substrate polishing system of claim 8, wherein pure water supplied from the first heating module before polishing the substrate has a temperature of 20 to 80° C.

10. The substrate polishing system of claim 8, wherein the slurry supplied from the second heating module in the polishing process has a temperature of 0 to 80° C.

11. The substrate polishing system of claim 8, wherein the cooling module supplies the cooled slurry to the polishing pad in order to reduce the temperature of the polishing pad in the last period of the polishing process.

12. The substrate polishing system of claim 11, further including a pure water supply module for supplying pure water to the polishing pad at a flow rate of 9 to 13 lpm in the last period of the polishing process.

13. The substrate polishing system of claim 11, wherein the pressure for pressing the substrate against the polishing pad is reduced in the last period of the polishing process.

14. The substrate polishing system of claim 13, wherein the pressure for pressing the substrate in the last period of the polishing process is ⅔ of the pressure for pressing the substrate in the polishing process.

15. A substrate polishing method for polishing a substrate through a polishing pad, the substrate polishing method comprising the steps of:
controlling the temperature of the polishing pad to a first temperature in the early period of the polishing process of the substrate;
controlling the temperature of the polishing pad to a second temperature in the middle period of the polishing process of the substrate; and
controlling the temperature of the polishing pad to a third temperature in the last period of the polishing process of the substrate.

16. The substrate polishing method of claim 15, wherein the step of controlling the temperature of the polishing pad to the first temperature includes a step of supplying heated pure water to the polishing pad to increase the temperature of the polishing pad to the first temperature.

17. The substrate polishing method of claim 15, wherein the step of controlling the temperature of the polishing pad to the second temperature includes a step of controlling the temperature of the polishing pad to the second temperature by adjusting the temperature of the slurry supplied to the polishing pad.

18. The substrate polishing method of claim 15, wherein the step of controlling the temperature of the polishing pad to the third temperature includes a step of supplying the cooled slurry to the polishing pad.

19. The substrate polishing method of claim 15, wherein the step of controlling the temperature of the polishing pad to the third temperature includes a step of supplying pure water to the polishing pad at a flow rate of 9 to 13 lpm.

20. The substrate polishing method of claim 15, wherein the step of controlling the temperature of the polishing pad to the third temperature includes a step of reducing the pressure for pressing the substrate against the polishing pad.
